(19) United States
(12) Patent Application Publication
(10) Pub. No.: US 2024/0153885 A1
(43) Pub. Date: May 9, 2024

(54) SEMICONDUCTOR DEVICES WITH ELECTRICAL INSULATION FEATURES AND ASSOCIATED PRODUCTION METHODS

(71) Applicant: Infineon Technologies AG, Neubiberg (DE)

(72) Inventors: Rainer Markus SCHALLER, Aichen (DE); Martin MAYER, Nittendorf (DE); Volker STRUTZ, Tegernheim (DE)

(21) Appl. No.: 18/498,537

(22) Filed: Oct. 31, 2023

(30) Foreign Application Priority Data
Nov. 8, 2022 (DE) 102022129478.1

(51) Int. Cl. H01L 23/552; G01R 15/20; G01R 19/00; H01L 21/48; H01L 23/00; H01L 23/495

(52) U.S. Cl. CPC H01L 23/552; G01R 15/202; G01R 19/0092; H01L 21/4803; H01L 21/4846; H01L 23/49534; H01L 23/49589; H01L 24/48; H01L 2224/48091; H01L 2224/48245

(57) ABSTRACT

A semiconductor device contains an electrically conductive carrier and a semiconductor chip arranged on the carrier. Furthermore, the semiconductor device contains a layer stack arranged between the carrier and the semiconductor chip and having a plurality of dielectric layers. The layer stack galvanically isolates the semiconductor chip and the carrier from one another. At least one of the plurality of dielectric layers is coated with an electrically conductive coating.

### CROSS-REFERENCE TO RELATED APPLICATION

This application claims priority to German Patent Application No. 102022129478.1 filed on Nov. 8, 2022, the content of which is incorporated by reference herein in its entirety.

### TECHNICAL FIELD

The present disclosure relates to semiconductor devices with electrical insulation features and associated production methods.

### BACKGROUND

In semiconductor devices, high electric voltage differences between individual device components may occur during operation. By way of example, increased electric potential differences may arise in a current sensor between a busbar and a sensor chip arranged thereabove. Depending on material properties and a relative arrangement of the device components, increased voltage differences may lead to enormously high electric field strengths in specific spatial regions of the device. Device components arranged there may be subject to wear as a result of the high electric field strengths, and in the worst case this wear may lead to failure of the device. Manufacturers and developers of semiconductor devices constantly endeavour to improve their products. In this context, it may be of particular interest both to lengthen the lifetime of the devices and to ensure their continuously safe operation.

### SUMMARY

Various aspects relate to a semiconductor device. The semiconductor device includes an electrically conductive carrier and a semiconductor chip arranged on the carrier. The semiconductor device furthermore includes a layer stack arranged between the carrier and the semiconductor chip and including a plurality of dielectric layers. The layer stack galvanically isolates the semiconductor chip and the carrier from one another. At least one of the plurality of dielectric layers is coated with an electrically conductive coating.

Various aspects relate to a semiconductor device. The semiconductor device includes an electrically conductive carrier and a dielectric structure arranged on the carrier. The semiconductor device furthermore includes a semiconductor chip arranged on a mounting surface of the dielectric structure. The dielectric structure includes a plurality of elevations which project from the mounting surface and surround the semiconductor chip. The dielectric structure galvanically isolates the semiconductor chip and the carrier from one another. The elevations are configured to enlarge a creepage path between the semiconductor chip and the carrier.

Various aspects relate to a method for producing a semiconductor device. The method includes fabricating a dielectric wafer based on a molding technique, wherein the dielectric wafer has a plurality of depressions. The method furthermore includes singulating the dielectric wafer into a plurality of dielectric shells. The method furthermore includes mounting a semiconductor chip in a dielectric shell. The method furthermore includes mounting the dielectric shell on an electrically conductive carrier, wherein the dielectric shell galvanically isolates the semiconductor chip and the carrier from one another.

### BRIEF DESCRIPTION OF THE DRAWINGS

Devices and methods in accordance with the disclosure are explained in greater detail below with reference to drawings. The elements shown in the drawings are not necessarily rendered in a manner true to scale relative to one another. Identical reference signs may designate identical components.

FIG. 1 schematically shows a perspective view of a semiconductor device 100.

FIG. 2 schematically shows a cross-sectional side view of a semiconductor device 200 and also field lines of an electric field that occurs in the semiconductor device 200.

FIG. 3 schematically shows a cross-sectional side view of a semiconductor device 300 in accordance with the disclosure.

FIG. 4 schematically shows a cross-sectional side view of a semiconductor device 400 in accordance with the disclosure and also field lines of an electric field that occurs in the semiconductor device 400.

FIG. 5 schematically shows a cross-sectional side view of a semiconductor device 500 in accordance with the disclosure.

FIG. 6 schematically shows a cross-sectional side view of a semiconductor device 600 in accordance with the disclosure.

FIG. 7 schematically shows a cross-sectional side view of a semiconductor device 700 in accordance with the disclosure.

FIG. 8 schematically shows a cross-sectional side view of a semiconductor device 800 in accordance with the disclosure.

FIGS. 9A to 9C schematically show a cross-sectional side view and detail views of a semiconductor device 900 in accordance with the disclosure.

FIG. 10 schematically shows a cross-sectional side view of a semiconductor device 1000 in accordance with the disclosure.

FIG. 11 shows a flow diagram of a method for producing a semiconductor device in accordance with the disclosure.

FIGS. 12A to 12G schematically show a cross-sectional side view of a method for producing a semiconductor device 1200 in accordance with the disclosure.

FIG. 13 shows a cross-sectional side view of a dielectric shell 1300 in accordance with the disclosure.

FIG. 14 shows a cross-sectional side view of a dielectric shell 1400 in accordance with the disclosure.

FIG. 15 schematically shows a cross-sectional side view of a semiconductor device 1500 in accordance with the disclosure.

FIG. 16 schematically shows a cross-sectional side view of a semiconductor device 1600 in accordance with the disclosure.

FIG. 17 schematically shows a cross-sectional side view of a semiconductor device 1700 in accordance with the disclosure.

### DETAILED DESCRIPTION

In the following description, reference is made to the accompanying drawings. The drawings illustrate concrete implementations in which the present disclosure can be implemented in practice by way of example. The following detailed description should not be understood in a limiting sense here. Some figures may illustrate dimensions of the devices shown therein and of the components thereof. The dimensions indicated are merely by way of example and are not intended to be limiting in any way. Each of the dimensions indicated may deviate downward or upward by up to approximately 10%, for example.

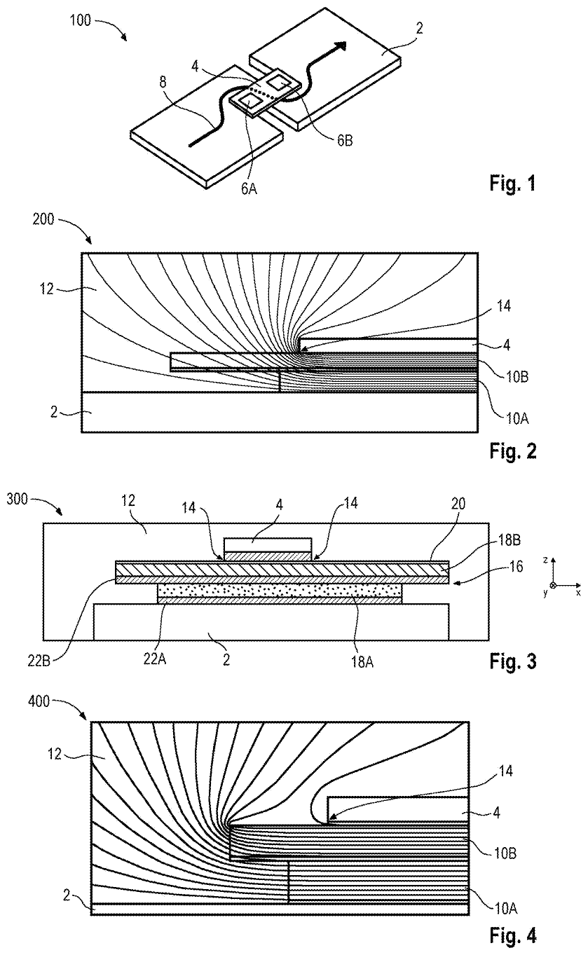

FIGS. 1 and 2 and also the description thereof are intended to illustrate qualitatively and by way of example a technical problem addressed by the present disclosure. However, the present disclosure is not restricted to the device types shown in FIGS. 1 and 2.

The semiconductor device 100 in FIG. 1 can have a carrier (or chip carrier) 2 and a semiconductor chip 4 arranged thereabove. The semiconductor chip 4 can be for example a magnetic field sensor chip with at least one sensor element. In the specific example in FIG. 1, the semiconductor chip 4 can correspond to a differential magnetic field sensor chip with two Hall sensor elements 6A, 6B.

The electrically conductive carrier 2 can fulfil the function of a busbar and can be configured to carry an electric measurement current 8. In the example shown, the carrier 2 or the busbar formed by it can have two indentations, such that the measurement current 8 can take an s-shaped course around the two sensor elements 6A, 6B. A magnetic field can be induced at the locations of the sensor elements 6A, 6B by the measurement current 8. The semiconductor chip 4 can be configured to detect the induced magnetic field at the positions of the sensor elements 6A, 6B. The intensity of the measurement current 8 can be determined based on the detected magnetic field (or based on an associated differential measurement signal). For this reason, the semiconductor chip 4 or the semiconductor device 100 can also be referred to as a current sensor.

The semiconductor device 200 in FIG. 2 can have one or more features of the semiconductor device 100 in FIG. 1. The semiconductor device 200 can contain a carrier 2 and a semiconductor chip 4 arranged above the carrier 2. A stack of dielectric layers 10 can be arranged between the carrier 2 and the semiconductor chip 4. In the example shown, the layer stack can have two dielectric layers 10A, 10B. The device components mentioned can be at least partly encapsulated by an encapsulation material 12.

Large electric potential differences between the carrier 2 and the semiconductor chip 4 can occur during operation of the semiconductor device 200. By way of example, such voltage differences can assume values of more than 1000 volts. A galvanic isolation or galvanic insulation between the carrier 2 and the semiconductor chip 4 can be provided by the dielectric layers 10A, 10B arranged therebetween. Since the dielectric layers 10A, 10B have an electrical insulation capability, high electric field strengths can build up in specific spatial regions of the semiconductor device 200. In FIG. 2, an electric field that occurs within the semiconductor device 200 is illustrated by electric field lines.

In the case shown, by way of example, a compression of the electric field lines can occur in a (spatial) region 14 at which the semiconductor chip 4, the encapsulation material 12 and the upper dielectric layer 10B adjoin one another. In other words, comparatively high electric field strengths can occur in the region 14. Materials arranged at the region 14 can be greatly stressed by the high electric field strengths, which can be problematic in particular for materials having a limited insulation ability. By way of example, an epoxy-, silicone- or acrylate-based adhesive layer arranged between the top side of the upper dielectric layer 10B and the underside of the semiconductor chip 4 may not necessarily be configured for a strong electrical insulation. The stress described may then lead to an accelerated aging of the materials, which may result in undesired electrical discharges within the device and, in the worst case, in failure of the device.

Example semiconductor devices in accordance with the disclosure and methods for producing such semiconductor devices are described below. The semiconductor devices can provide reduced internal electric field strengths and can thus contribute at least in part to a solution to the technical problem described above.

The semiconductor device 300 in FIG. 3 can have one or more features of semiconductor devices described above. The semiconductor device 300 can contain an electrically conductive carrier 2 and a semiconductor chip 4 arranged on (or above) the carrier 2. A layer stack 16, which can have a plurality of dielectric layers 18A, 18B, can be arranged between the carrier 2 and the semiconductor chip 4. The layer stack 16 can be configured to galvanically isolate the carrier 2 and the semiconductor chip 4 from one another. At least one of the dielectric layers 18A, 18B can be coated with an electrically conductive coating 20.

The electrically conductive coating 20 can generally be produced from any suitable electrically conductive material. Preferably, the electrically conductive coating 20 can be fabricated from a metal or a metal alloy. In this context, the electrically conductive coating 20 can contain at least one out of copper, nickel, iron, cobalt, palladium, silver, gold, aluminum, or alloy thereof.

A dimension (or thickness) of the electrically conductive coating 20 in the z-direction can generally be in a range of approximately 10 nm to approximately 35 μm. In one specific example, the electrically conductive coating 20 can be formed by one or more metal layers, each of which can have a typical layer thickness in a range of approximately 15 nm to approximately 20 nm. In further examples, the thickness of the electrically conductive coating 20 can also be chosen differently. In this case, the thickness can be in a range with a lower limit of approximately 10 nm and an upper limit of approximately 25 nm, 50 nm, 100 nm, 250 nm, 500 nm, 1 μm, 5 μm, 15 μm, 25 μm or 35 μm. The fabrication of the electrically conductive coating 20 can be based on any suitable process. By way of example, the electrically conductive coating 20 can be produced by at least one of the following techniques: atomic layer deposition, electroplating, electroless plating, electrodeposition, cold gas spraying, plasma dust spraying, plasma-induced spraying, vapor deposition, printing, etc.

As viewed in the z-direction, one or more openings can be formed in the electrically conductive coating 20. The openings can be configured to prevent or at least reduce any arising of eddy currents in the electrically conductive coating 20. The openings can have any desired number, shape and/or arrangement as long as the electrically conductive coating 20 is interrupted by the openings in such a way that eddy currents can be prevented from arising during operation of the semiconductor device 300. By way of example, the individual openings can have round, circular, oval, rectangular, square shapes, or combinations thereof. In this case, the openings can form for example a comb structure, a net structure, a honeycomb structure, or combinations thereof.

In the example in FIG. 3, the layer stack 16 can have two dielectric layers 18A, 18B. In this case, the upper dielectric layer 18B can extend at least partly beyond the edges of the lower dielectric layer 18A. An electrical creepage path between the carrier 2 and the semiconductor chip 4 can be lengthened as a result. In particular, as viewed in the z-direction, a footprint of the lower dielectric layer 18A can be arranged (in particular completely) within a footprint of the upper dielectric layer 18B.

The dielectric layers 18A, 18B can be fabricated from an identical material or from different materials. In one example, the dielectric layers 18A, 18B can contain or be produced from an inorganic material. The inorganic material can comprise for example at least one out of a glass material or a ceramic material. Alternatively or additionally, the dielectric layers 18A, 18B can contain or be produced from an organic material. The organic material can comprise for example at least one out of a polymer, a polyimide, Kapton®, an epoxy or a silicone. In the nonlimiting example shown in FIG. 3, the lower dielectric layer 18A can be produced from a glass material and have a dimension in a range of approximately 100 μm to approximately 200 μm in the z-direction. The upper dielectric layer 18B can for example be fabricated from Kapton® and have a dimension in a range of approximately 50 μm to approximately 100 μm in the z-direction.

The lower dielectric layer 18A can be secured to the carrier 2 by a first securing layer 22A. In an analogous manner, the upper dielectric layer 18B can be secured to the lower dielectric layer 18A by a second securing layer 22B. The securing layers 22A, 22B can in particular be electrically conductive and be fabricated from a material that provides sufficient adhesion between the components to be secured to one another. By way of example, each of the securing layers 22A, 22B can correspond to a DAF (die attach film) film, which can contain industrial carbon black, for example. A dimension of such a DAF film in the z-direction can have a value of approximately 10±5 μm.

The implementation of the carrier 2 is not limited to a specific carrier type. In particular, the carrier 2 can be at least partly produced from an electrically conductive material, and so a galvanic isolation between the carrier 2 and the semiconductor chip 4 may be necessary. In the example shown, the carrier 2 can be a leadframe, which can be at least partly fabricated from a metal or a metal alloy. The leadframe can have one or more die pads and also one or more leads. The semiconductor chip 4 can be mounted in particular on the top side of a die pad. The leadframe or the die pad can be configured as a busbar, as already described in association with FIG. 1.

The encapsulation material 12 can contain an electrically insulating material or can be fabricated from such a material. One or more components of the semiconductor device 300 can be encapsulated by the encapsulation material 12 and thereby protected against external influences, such as moisture or mechanical impacts, for example. The encapsulation material 12 can form a housing for the device components, and so the semiconductor device 300 may also be referred to as a semiconductor housing or semiconductor package. The encapsulation material 12 can comprise at least one out of a mold compound, an epoxy, an imide, a thermoplastic, a thermosetting polymer, a polymer mixture, a glob top material, a laminate, etc. Various techniques can be used for producing the housing, for example at least one out of compression molding, injection molding, powder molding, liquid molding, map molding, lamination, etc.

The semiconductor device 300 can have further components, not shown in FIG. 3 for the sake of simplicity. By way of example, the semiconductor device 300 can optionally have one or more electrical connection elements (e.g., bond wires) which can electrically connect the semiconductor chip 4 to leads (not shown) of the carrier 2. The leads can at least in part not be covered by the encapsulation material 12, such that the semiconductor chip 4 can be electrically contacted from outside the housing.

As already described in association with FIG. 2, during operation of the semiconductor device 300, locally increased electric field strengths within the semiconductor device 300 can occur on account of voltage differences that occur between the carrier 2 and the semiconductor chip 4. By way of example, the electric field strength can be increased in a boundary region 14 at which the semiconductor chip 4, the layer stack 16 (or the upper dielectric layer 18B) and the encapsulation material 12 adjoin one another, as already described in association with FIG. 2. In addition, on account of relative arrangements, geometric shapes and/or material properties of the device components, increased electric field strengths can also occur in other spatial regions, for example at an edge or a tip of the semiconductor chip 4.

The electrically conductive coating 20 can be configured to reduce such locally increased electric field strengths. The electrically conductive coating 20, one or more of the securing layers 22A, 22B and the carrier 2 can be electrically conductive, while the intervening layers 18A, 18B can be dielectrics. The components mentioned can thus form one or more capacitors within the semiconductor device 300. In one example, the electrically conductive coating 20 and the upper securing layer 22B can form a first and a second electrode of a capacitor with an intervening dielectric 18B. In a further example, the two securing layers 22A, 22B and the intervening dielectric layer 18A can form a further capacitor. Ultimately the different layers can form a total capacitance which can be directed oppositely to the increased electric field, as a result of which the electric field strength in a selected spatial region can be reduced. To put it another way, the use of the electrically conductive coating 20 makes it possible to effect a capacitive control of the electric field within the semiconductor device 300.

The semiconductor device 400 in FIG. 4 may be similar at least in part to semiconductor devices described above. In contrast to the semiconductor device 200 in FIG. 2, the semiconductor device 400 can additionally have an electrically conductive coating arranged on the top side of the upper dielectric layer 10B, as described in association with FIG. 3. Whereas the electric field lines in the region 14 are compressed in the example in FIG. 2, the electric field lines in the region 14 can be expanded by the use of the electrically conductive coating or the capacitance(s) based thereon in the example in FIG. 4. The use of the electrically conductive coating thus makes it possible to control the electric field distribution within the semiconductor device 400 and to reduce increased electric field strengths. Accordingly, the electrically conductive coating may also be referred to as a field control layer.

In addition to the reduction of the electric field strength as already described, the semiconductor devices in accordance with the disclosure described herein can provide the technical effects described below. Merely by way of example, reference may be made hereinafter to the semiconductor device 300 in FIG. 3. It is clear, however, that the technical effects mentioned can also be provided by any other semiconductor device described herein.

Wear of the device components can be prevented by use of the electrically conductive coating 20 and the reduction—brought about by the latter—of electric field strengths within the semiconductor device 300. As a result, premature aging of the components can be prevented and the lifetime thereof can be increased. The risk of failure of the semiconductor device 300 can be reduced as a result. The lengthened lifetime enables energy resources and material resources to be saved.

The reduction of the electric field strengths makes it possible to prevent electrical discharges, electrical partial discharges and/or air breakdowns within the semiconductor device 300. On account of aging processes, under certain circumstances air volumes or air bubbles can be formed in the device, for example at an interface between the encapsulation material 12 and the layer stack 16. On account of the reduced electric field strengths, it is possible to reduce the risk of discharges along air clearances in the air volumes.

The reduction of the electric field strengths makes it possible to dispense with additional components for an improved galvanic insulation within the semiconductor device or in a superordinate system. In the semiconductor devices in accordance with the disclosure, a required galvanic isolation can be provided completely and in particular by the use of the electrically conductive coating 20. The devices described herein therefore constitute simplified and cost-effective solutions.

On account of the achieved reduction of electric field strengths, insulation standards specified by industry standards can be complied with. The standards IEC 60664 and IEC 60747-17 may be mentioned as industry standards available at the time of this disclosure. In this context, however, it should be noted that the present disclosure is not in any way limited to the aforementioned standards or device types associated therewith. The concepts described herein can of course also be used in other technical fields or devices.

The semiconductor devices described herein can be used for example in highly efficient resource-conserving electric power drives. Power drives can contribute at least in part to reducing the global carbon dioxide emissions. The semiconductor devices described herein can thus contribute at least indirectly to green technology solutions, e.g., to climate-friendly solutions that provide a reduced energy and material consumption.

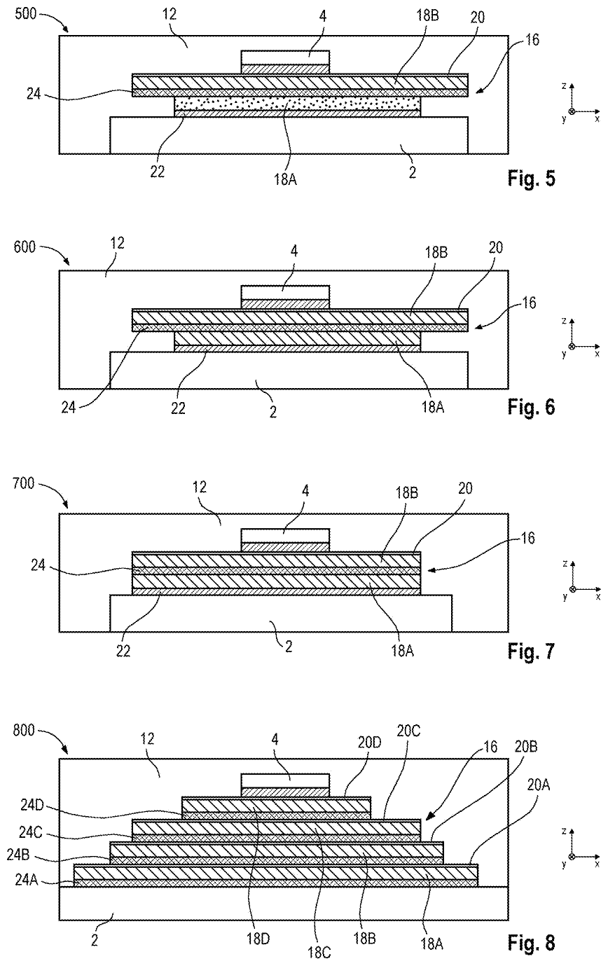

The semiconductor device 500 in FIG. 5 can have one or more features of semiconductor devices described above. In the example shown, an adhesive layer 24 can be arranged between the two dielectric layers 18A, 18B and secure the latter to one another. The adhesive layer 24 can in particular contain an electrically conductive material or be fabricated from such a material. In this context, the adhesive layer 24 can contain an electrically conductive filler, such as graphite powder, for example. A dimension of the adhesive layer 24 in the z-direction can be in a range of approximately 15 μm to approximately 25 μm. Analogously to FIG. 3, in FIG. 5 one or more capacitances can be formed by at least one out of the electrically conductive coating 20, the adhesive layer 24, the securing layer 22 and the carrier 2. It is thereby possible to provide a capacitive control of the electric field within the semiconductor device 500.

The semiconductor device 600 in FIG. 6 can have one or more features of semiconductor devices described above. In the case shown, it is possible by way of example for each of the dielectric layers 18A, 18B to be a Kapton® layer, which can be similar to the dielectric layer 18B in FIG. 3, for example. In other examples, however, a different material described in association with FIG. 3 can also be used for the dielectric layer 18B. Furthermore, the securing layer 22 and the adhesive layer 24 can correspond to corresponding layers in FIGS. 3 and 5.

The semiconductor device 700 in FIG. 7 may be similar to the semiconductor device 600 in FIG. 6. In contrast to FIG. 6, the dielectric layers 18A, 18B in FIG. 7, as viewed in the z-direction, can be substantially congruent and have similar footprints.

The semiconductor device 800 in FIG. 8 can have one or more features of semiconductor devices described above. In contrast to previous examples, the layer stack 16 can have more than two dielectric layers. In the case shown, the layer stack 16 can have by way of example four dielectric layers 18A to 18D, such as four Kapton® layers, for example. In other examples, however, one or more other materials described above can also be used for the dielectric layers 18A to 18D. Furthermore, the semiconductor device 800 can contain a plurality of electrically conductive coatings 20A to 20D, which can be arranged on the top sides of the dielectric layers 18A to 18D. Securing the aforementioned components among one another can be achieved by way of a plurality of adhesive layers 24A to 24D.

In the example shown, the dielectric layers 18A to 18D can be arranged in staircase-shaped fashion. In this case, as viewed in the z-direction, a footprint of a dielectric layer can be arranged (in particular completely) within a footprint of the underlying dielectric layer. The staircase-shaped arrangement of the dielectric layers 18A to 18D and of the electrically conductive coatings 20A to 20D arranged thereon can provide a lengthened creepage path between the carrier 2 and the semiconductor chip 4. Analogously to previous examples, in FIG. 8 the aforementioned components can form one or more capacitances, thereby making it possible to provide a capacitive control of the electric field within the semiconductor device 800.

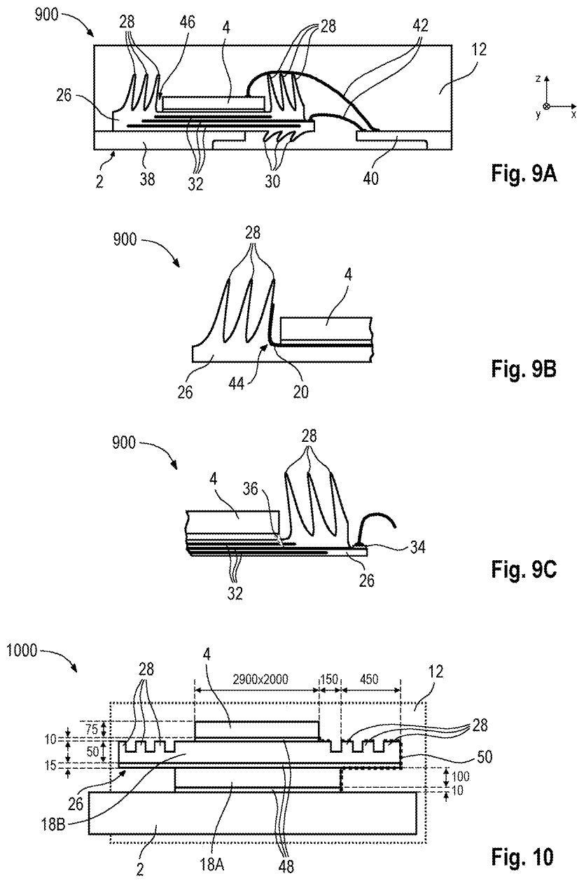

The semiconductor device 900 in FIG. 9 can have one or more features of semiconductor devices described above. FIG. 9A shows a side view of the entire semiconductor device 900, while FIGS. 9B and 9C illustrate detail views of parts of the semiconductor device 900. The semiconductor device 900 can have an electrically conductive carrier 2 and a dielectric structure 26 arranged on the carrier 2. A semiconductor chip 4 can be arranged on a mounting surface of the dielectric structure 26. The dielectric structure 26 can galvanically isolate the semiconductor chip 4 and the carrier 2 from one another. Furthermore, the dielectric structure 26 can comprise a plurality of elevations 28 which can project from the mounting surface and surround the semiconductor chip 4.

In the example shown, the mounting surface can be arranged substantially in the x-y-plane and the elevations 28 can extend substantially in the z-direction. In this case, at least some of the elevations 28 can project beyond the semiconductor chip 4 in the z-direction. In the case shown, the semiconductor chip 4 can be surrounded by three elevations 28 on the left and right, by way of example. In further examples, the number of elevations 28 can be chosen differently, as necessary. As viewed in the z-direction, the elevations 28 can enclose (in particular completely) the mounting surface or the semiconductor chip 4 mounted thereon. Besides the elevations 28 projecting from the mounting surface of the dielectric structure 26, the dielectric structure 26 can optionally have one or more further elevations 30 on its underside.

The elevations 28 can be configured to enlarge a creepage path between the carrier 2 and the semiconductor chip 4. As a result, inter alia, migration effects within the semiconductor device 900 can be attenuated and a breakdown strength can be increased. In this context, the elevations 28 can contain a plurality of shielding structures and/or rib structures or be embodied as such. Structures shaped in this way make it possible to provide particularly long creepage paths between the carrier 2 and the semiconductor chip 4.

The geometric shape of the elevations 28 can be directed oppositely to increased electric fields within the semiconductor device 900, which fields may arise on account of electric potential differences between the carrier 2 and the semiconductor chip 4. In the case shown, the shielding structures and/or rib structures 28 can for example be chamfered and thereby provide a reduction of increased electric field strengths. In the example shown, the elevations 28 can in particular be inclined in the direction of the semiconductor chip 4 and form an angle of less than 90 degrees with the mounting surface of the dielectric structure 26.

Besides the described reduction of increased electric field strengths, the elevations 28 can provide one or more adhesive stop features 46. Since the elevations 28 project from the mounting surface, they can prevent for example lateral spreading of an adhesive used between the mounting surface and the semiconductor chip 4.

The semiconductor device 900 can have one or more electrically conductive layers 32 embedded in the dielectric structure 26 and configured to form one or more capacitors. In this regard, the electrically conductive layers 32 may be similar in particular to the electrically conductive coatings 20 described in association with previous figures. That means that the capacitance formed by the at least one capacitor can be configured to reduce an electric field strength in a selected spatial region of the semiconductor device 900. The electrically conductive layers 32 can provide a capacitive field control of the electric field within the semiconductor device 900. As viewed in the z-direction, the electrically conductive layers 32 can have openings in order to prevent eddy currents from arising.

The geometric shape and/or the relative arrangement of the electrically conductive layers 32 can be chosen such that a discharge path extending from the semiconductor chip 4 through the dielectric structure 26 to the carrier 2 will be lengthened. In the example shown, the electrically conductive layers 32 can be arranged in staircase-shaped fashion for this purpose. In this case, as viewed in the z-direction, a footprint of an electrically conductive layer 32 can be arranged (in particular completely) within a footprint of the underlying electrically conductive layer 32. The staircase-shaped arrangement of the electrically conductive layers 32 can prevent a discharge (or partial discharge) from taking place through the dielectric structure 26 on the shortest path in the z-direction. Rather, an electrical discharge can take place only along a lengthened path past the electrically conductive layers 32.

One or more of the electrically conductive layers 32 can be electrically connected to an electrical output 34. In the detail view in FIG. 9C, by way of example, the central layer 32 can be electrically connected to the electrical output 34. If a partial discharge 36 occurs between the semiconductor chip 4 and the connected electrically conductive layer 32, electric charges can flow via the connected electrically conductive layer 32 to the electrical output 34, e.g., the electrical output 34 can output a signal. The output signal can be forwarded for example to a comparator circuit for a detection of the partial discharge 36.

The semiconductor device 900 can have one or more electrically conductive (or antistatic) coatings 20 arranged between the mounting surface of the dielectric structure 24 and the semiconductor chip 4, as shown by way of example in the detail view in FIG. 9B. In the example shown, the electrically conductive coating 20 can extend over the mounting surface and at least partly along a side wall of an elevation 28 adjacent to the semiconductor chip 4. In this case, a transition from the mounting surface to the side wall of the adjacent elevation 28 can have in particular a rounded corner 44. The electrically conductive coating 20 shown in FIG. 9B may for example be similar to the electrically conductive coatings 20 described above in association with FIGS. 3 to 8 and fulfil similar functionalities.

The dielectric structure 26 can be arranged or secured in particular directly on the carrier 2. That means that an additional adhesive layer need not necessarily be used in order to secure the dielectric structure 26 to the carrier 2 sufficiently fixedly. The dielectric structure 26 can be fabricated from any suitable dielectric and can be produced based on any suitable method. In one specific example, the dielectric structure 26 can be produced based on a 3D printing method and can contain a printable dielectric material.

In the example in FIGS. 9A-9C, the carrier 2 can have one or more die pads 38 and also one or more leads 40. The semiconductor chip 4 can be electrically connected to the leads 40 by way of electrical connection elements 42. One or more device components can be encapsulated by an encapsulation material 12, wherein the leads 40 can at least in part not be covered by the encapsulation material 12, such that the semiconductor chip 4 can be electrically contacted from outside the encapsulation material 12. In the case shown, the electrical connection elements 42 can comprise or correspond to bond wires, for example. The elevations 28 can in particular be arranged below the bond wires 42 and be configured to mechanically support the bond wires 42, whereby sagging and/or bending of the bond wires 42 can be prevented.

The semiconductor device 1000 in FIG. 10 can have one or more features of semiconductor devices described above. The semiconductor device 1000 can contain a carrier 2 and a dielectric structure 26 arranged thereon. A semiconductor chip 4 can be arranged on the top side of the dielectric structure 26. In the case shown, the dielectric structure 26 can have by way of example two dielectric layers 18A, 18B, which may be similar to the dielectric layers 18A, 18B in FIG. 3, for example. In a nonlimiting example, the lower dielectric layer 18A can be fabricated from a glass material and the upper dielectric layer 18B can correspond to a polyimide tape. The aforementioned device components can be secured to one another by adhesive layers 48. Dimensions of the device components illustrated in FIG. 10 are indicated in μm.

In the example shown, the top side of the upper dielectric layer 18B can be structured and have a plurality of elevations 28 (or depressions). The dielectric layer 18B can be structured by any suitable technique. In one example, the dielectric layer 18B can be a Kapton® tape which can be structured by a laser. In another example, the dielectric layer 18B can be fabricated from a glass material which can be structured by an etching process. The elevations 28 can enlarge a creepage path 50 between the carrier 2 and the semiconductor chip 4. In FIG. 10, an example creepage path 50 is indicated by a dashed line.

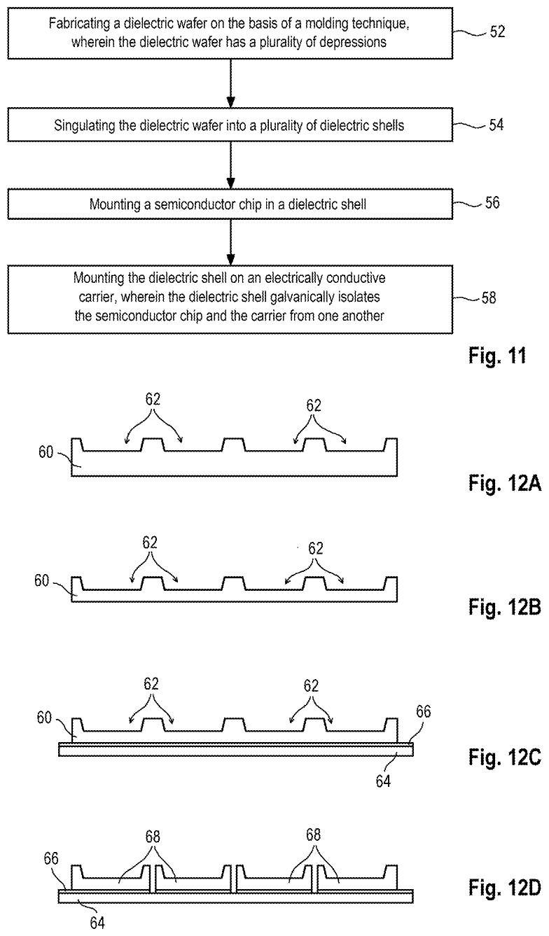

FIG. 11 shows a flow diagram of a method for producing a semiconductor device in accordance with the disclosure. The method is illustrated and described in a general way in order to describe aspects of the disclosure qualitatively. The method can have further aspects. By way of example, the method can be extended by one or more of the aspects mentioned in connection with other figures described herein.

At 52, a dielectric wafer can be fabricated based on a molding technique, wherein the dielectric wafer has a plurality of depressions. At 54, the dielectric wafer can be singulated into a plurality of dielectric shells. At 56, a semiconductor chip can be mounted in a dielectric shell. At 58, the dielectric shell can be mounted on an electrically conductive carrier, wherein the dielectric shell galvanically isolates the semiconductor chip and the carrier from one another.

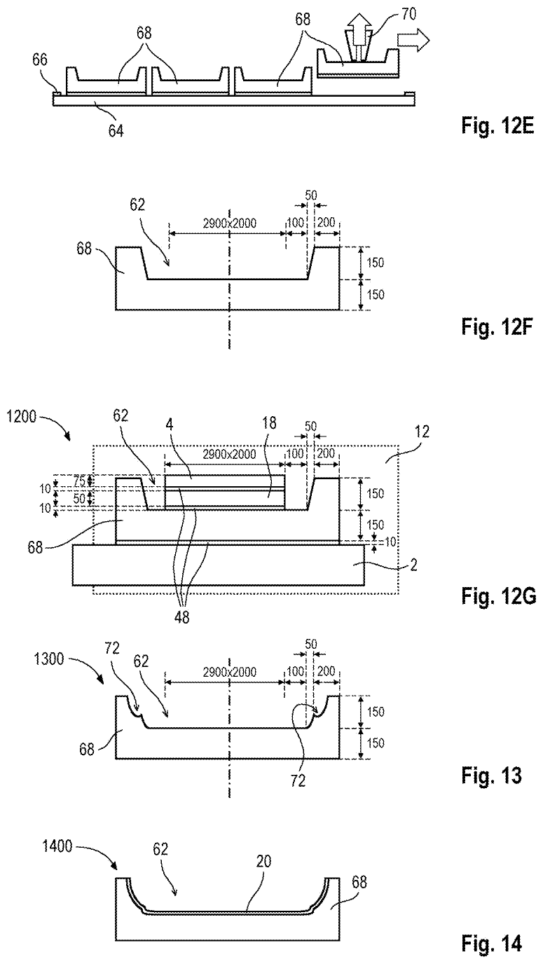

The method in FIGS. 12A-12G can be regarded as a more detailed version of the method in FIG. 11. In FIG. 12A, a dielectric wafer 60 can be fabricated based on a molding technique. The dielectric wafer 60 can contain or be fabricated from at least one out of a mold compound, an epoxy, an imide, a thermoplastic, a thermosetting polymer or a polymer mixture. The production of the dielectric wafer 60 can be based for example on at least one out of compression molding, injection molding, powder molding, liquid molding or map molding. During the fabrication of the dielectric wafer 60, a plurality of depressions 62 can be formed in the top side of the wafer. For example, a molding tool used for the molding process can be correspondingly shaped for this purpose. In the example side view in FIG. 12, the depressions 62 can have a trapezoidal shape. In further examples, the shape of the depressions 62 can also be chosen differently.

In FIG. 12B, the dielectric wafer 60 can optionally be thinned to a desired target thickness if a suitable thickness is not yet present. In the case shown, material can be removed from the rear side of the dielectric wafer 60, for example using a grinding process.

In FIG. 12C, the dielectric wafer 60 can be mounted on a temporary carrier. In the example shown, the temporary carrier can comprise a dicing film 64 and a die attach film 66 arranged thereon. The dielectric wafer 60 can be secured on the top side of the die attach film 66. Before the dielectric wafer 60 is mounted on the temporary carrier, optionally a suitable rear-side protection (not shown) can be secured on the rear side of the dielectric wafer 60. By way of example, such a rear-side protection can contain or correspond to an epoxy resin film. The epoxy resin film can be laminated onto the rear side of the dielectric wafer 60, for example.

In FIG. 12D, the dielectric wafer 60 can be singulated into a plurality of dielectric shells 68. By way of example, at least one out of a mechanical dicing process, a stealth dicing process, a sawing process, etc. can be employed for this purpose.

In FIG. 12E, the individual dielectric shells 68 can be removed from the temporary carrier and rearranged for further method steps, using a pick-and-place technique. A conventional pick-and-place tool 70 can be used here.

FIG. 12F shows by way of example a dielectric shell 68 produced by the method steps described above. Various dimensions of the dielectric shell 68 in μm are illustrated here.

In FIG. 12G, a dielectric layer 18 with a semiconductor chip 4 arranged thereon can be positioned in the depression 62 of a fabricated dielectric shell 68. In one example, the dielectric layer 18 can be a polyimide tape. The dielectric shell 68 and the components arranged therein can be arranged on the top side of an electrically conductive carrier 2. The aforementioned components can be secured to one another by a plurality of adhesive layers 48, as illustrated in FIG. 12G. Furthermore, the components can be at least partly encapsulated by an encapsulation material 12.

FIG. 12G shows a semiconductor device 1200 produced by the method in FIG. 12. Analogously to examples described above, the arrangement of the semiconductor chip 4 in the depression 62 of the dielectric shell 68 makes it possible to lengthen a creepage path between the carrier 2 and the semiconductor chip 4. Dimensions of the device components illustrated in FIG. 12G are indicated in μm.

FIG. 13 shows a dielectric shell 1300, which may be similar to the dielectric shell 68 in FIG. 12F, for example. The dielectric shell 1300 may have been produced based on the described method in FIG. 12, for example. The dielectric shell 68 in FIG. 13 can have one or more depressions 72 at its inner side walls. As a result, the inner side walls can form a multistep structure. The depressions 72 make it possible to further enlarge a creepage path between a semiconductor chip arranged in the dielectric shell 1300 and an electrically conductive carrier arranged below the dielectric shell 1300. Dimensions of the dielectric shell 1300 illustrated in FIG. 13 are indicated in μm.

FIG. 14 shows a dielectric shell 1400, which may be similar to the dielectric shell 1300 in FIG. 13, for example, and may have been produced based on the method in FIG. 12, for example. The dielectric shell 1400 in FIG. 14 can have an electrically conductive coating 20 arranged on a base surface of the dielectric shell 1400. In further method steps, a semiconductor chip can be mounted on the electrical conductive coating 20 in the dielectric shell 1400.

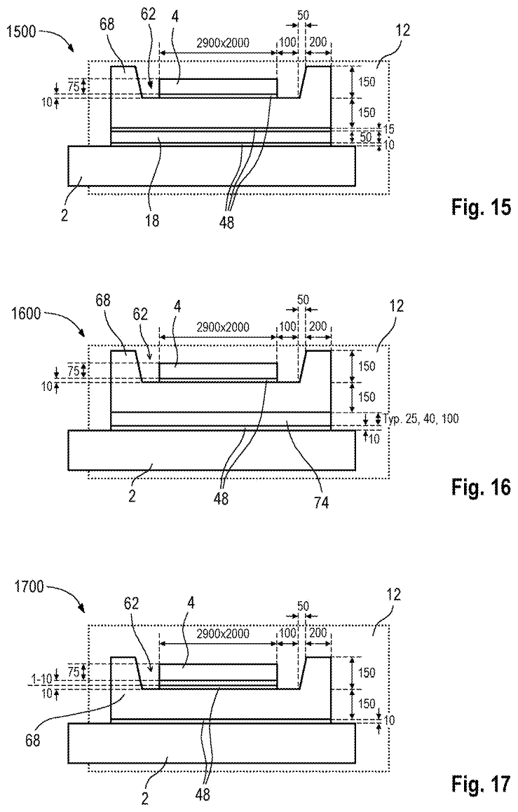

FIG. 15 shows a semiconductor device 1500, which may be similar to the semiconductor device 1200 in FIG. 12G, for example, and may have been produced based on the method in FIG. 12, for example. In contrast to FIG. 12G, in FIG. 15 it is possible for the dielectric layer 18 not to be arranged in the depression 62 of the dielectric shell 68, but rather outside the dielectric shell 68 between the top side of the carrier 2 and the underside of the dielectric shell 68. The dielectric layer 18 can be a polyimide tape, for example. Dimensions of the device components illustrated in FIG. 15 are indicated in μm.

FIG. 16 shows a semiconductor device 1600, which may be similar to the semiconductor device 1500 in FIG. 15, for example, and may have been produced based on the method in FIG. 12, for example. In contrast to FIG. 15, in FIG. 16 a rear-side protection 74 can be secured directly on the rear side of the dielectric shell 68. In one example, the rear-side protection 74 can contain or correspond to an epoxy resin film. The epoxy resin film may have been laminated onto the rear side of the dielectric shell 68, for example. Dimensions of the device components illustrated in FIG. 16 are indicated in μm.

FIG. 17 shows a semiconductor device 1700, which may be similar to the semiconductor device 1600 in FIG. 16, for example, and may have been produced based on the method in FIGS. 12A-12G, for example. In contrast to FIG. 16, the semiconductor device 1700 in FIG. 17 need not necessarily have a rear-side protection arranged on the rear side of the dielectric shell 68. Rather, the rear side of the dielectric shell 68 can be secured directly on the top side of the carrier 2 using an adhesive layer 48. Dimensions of the device components illustrated in FIG. 17 are indicated in μm.

It should be noted that a use of the concepts described herein is not restricted to a specific device type. In one example, the concepts described can be used in a current sensor as described by way of example in FIG. 1. That means that a semiconductor device in accordance with the disclosure can be part of a current sensor, for example. In a further example, the concepts described can find application in a gate driver or a discrete component. In particular, a use of the features described herein can be expedient in such devices which are configured to provide certain insulation functions, such as, for example, the already described galvanic isolation between a busbar and a semiconductor chip arranged thereabove.

### EXAMPLES

Semiconductor devices and associated production methods are explained below based on examples.

Example 1 is a semiconductor device, comprising:
an electrically conductive carrier; a semiconductor chip arranged on the carrier; and a layer stack arranged between the carrier and the semiconductor chip and comprising a plurality of dielectric layers, wherein the layer stack galvanically isolates the semiconductor chip and the carrier from one another, and wherein at least one of the plurality of dielectric layers is coated with an electrically conductive coating.

Example 2 is a semiconductor device according to example 1, wherein the coating is configured to reduce an electric field strength in a selected spatial region of the semiconductor device.

Example 3 is a semiconductor device according to example 1 or 2, wherein the spatial region comprises a boundary region at which the semiconductor chip, the layer stack and an encapsulation material encapsulating the semiconductor chip adjoin one another.

Example 4 is a semiconductor device according to example 2 or 3, wherein: the coating is configured to form an electrode of a capacitor, and the electric field strength is reduced based on a capacitance formed by the capacitor.

Example 5 is a semiconductor device according to any of the preceding examples, furthermore comprising: an adhesive layer comprising an electrically conductive filler and arranged between the carrier and the semiconductor chip.

Example 6 is a semiconductor device according to any of the preceding examples, furthermore comprising: a securing layer comprising industrial carbon black and arranged between the carrier and the semiconductor chip.

Example 7 is a semiconductor device according to one or more of examples 4 to 6, wherein a further electrode of the capacitor is formed by the carrier, the adhesive layer, the securing layer or a further electrically conductive coating of a dielectric layer of the layer stack.

Example 8 is a semiconductor device according to any of the preceding examples, wherein a plurality of openings are formed in the coating, and are configured to prevent eddy currents from arising in the coating.

Example 9 is a semiconductor device, comprising: an electrically conductive carrier; a dielectric structure arranged on the carrier; and a semiconductor chip arranged on a mounting surface of the dielectric structure, wherein the dielectric structure comprises a plurality of elevations which project from the mounting surface and surround the semiconductor chip, and wherein the dielectric structure galvanically isolates the semiconductor chip and the carrier from one another, and the elevations are configured to enlarge a creepage path between the semiconductor chip and the carrier.

Example 10 is a semiconductor device according to example 9, wherein the elevations comprise a plurality of chamfered shielding or rib structures.

Example 11 is a semiconductor device according to example 9 or 10, wherein a geometric shape of the elevations is directed oppositely to an electric field based on an electric potential difference between the semiconductor chip and the carrier.

Example 12 is a semiconductor device according to any of examples 9 to 11, furthermore comprising: a plurality of electrically conductive layers embedded in the dielectric structure and configured to form at least one capacitor, wherein a capacitance formed by the at least one capacitor is configured to reduce an electric field strength in a selected spatial region of the semiconductor device.

Example 13 is a semiconductor device according to example 12, wherein a geometric shape and relative arrangement of the electrically conductive layers are configured to lengthen a discharge path extending from the semiconductor chip through the dielectric structure to the carrier.

Example 14 is a semiconductor device according to example 12 or 13, wherein: at least one of the electrically conductive layers is electrically connected to an electrical output, and the electrical output outputs a signal if a partial discharge occurs between the semiconductor chip and the at least one of the electrically conductive layers in the dielectric structure.

Example 15 is a semiconductor device according to any of examples 9 to 14, wherein the dielectric structure is arranged directly on the carrier.

Example 16 is a semiconductor device according to any of examples 9 to 15, wherein the dielectric structure is produced based on a 3D printing method.

Example 17 is a semiconductor device according to any of examples 9 to 16, furthermore comprising: an electrically conductive coating arranged between the mounting surface of the dielectric structure and the semiconductor chip, wherein the coating is configured to reduce an electric field strength in a selected spatial region of the semiconductor device.

Example 18 is a semiconductor device according to any of examples 9 to 17, furthermore comprising: at least one bond wire, wherein the elevations are configured to mechanically support the at least one bond wire in order to prevent sagging or bending of the at least one electrical bond wire.

Example 19 is a method for producing a semiconductor device, wherein the method comprises: fabricating a dielectric wafer based on a molding technique, wherein the dielectric wafer has a plurality of depressions; singulating the dielectric wafer into a plurality of dielectric shells; mounting a semiconductor chip in a dielectric shell; and mounting the dielectric shell on an electrically conductive carrier, wherein the dielectric shell galvanically isolates the semiconductor chip and the carrier from one another.

Example 20 is a method according to example 19, furthermore comprising: forming a plurality of depressions in a surface of the dielectric shell, wherein the depressions are configured to enlarge a creepage path between the semiconductor chip and the carrier.

Example 21 is a method according to example 19 or 20, furthermore comprising: coating a base surface of the dielectric shell with an electrically conductive coating, wherein the semiconductor chip is arranged on the coating.

Although specific implementations have been illustrated and described herein, it is obvious to a person skilled in the art that a multiplicity of alternative and/or equivalent implementations can replace the specific implementations shown and described, without departing from the scope of the present disclosure. This application is intended to cover all adaptations or variations of the specific implementations discussed herein. Therefore, the intention is for this disclosure to be restricted only by the claims and the equivalents thereof.

1. A semiconductor device, comprising:
an electrically conductive carrier;
a semiconductor chip arranged on the electrically conductive carrier; and
a layer stack arranged between the electrically conductive carrier and the semiconductor chip and comprising a plurality of dielectric layers,
wherein the layer stack galvanically isolates the semiconductor chip and the electrically conductive carrier from one another, and
wherein at least one of the plurality of dielectric layers is coated with an electrically conductive coating.

2. The semiconductor device as claimed in claim 1, wherein the electrically conductive coating is configured to reduce an electric field strength in a selected spatial region of the semiconductor device.

3. The semiconductor device as claimed in claim 2, wherein the selected spatial region comprises a boundary region at which the semiconductor chip, the layer stack, and an encapsulation material encapsulating the semiconductor chip adjoin one another.

4. The semiconductor device as claimed in claim 2, wherein:
the electrically conductive coating is configured to form an electrode of a capacitor, and
the electric field strength is reduced based on a capacitance formed by the capacitor.

5. The semiconductor device as claimed in claim 1, furthermore comprising:
an adhesive layer comprising an electrically conductive filler and arranged between the electrically conductive carrier and the semiconductor chip.

6. The semiconductor device as claimed in claim 5, furthermore comprising:
a securing layer comprising an industrial carbon black and arranged between the electrically conductive carrier and the semiconductor chip.

7. The semiconductor device as claimed in claim 6, wherein a further electrode of the capacitor is formed by the electrically conductive carrier, the adhesive layer, the securing layer, or a further electrically conductive coating of a dielectric layer of the layer stack.

8. The semiconductor device as claimed in claim 1, wherein a plurality of openings are formed in the electrically conductive coating, and are configured to prevent eddy currents from arising in the electrically conductive coating.

9. A semiconductor device, comprising:
an electrically conductive carrier;
a dielectric structure arranged on the electrically conductive carrier; and
a semiconductor chip arranged on a mounting surface of the dielectric structure,
wherein the dielectric structure comprises a plurality of elevations which project from the mounting surface and surround the semiconductor chip, and
wherein the dielectric structure galvanically isolates the semiconductor chip and the electrically conductive carrier from one another, and the elevations are configured to enlarge a creepage path between the semiconductor chip and the electrically conductive carrier.

10. The semiconductor device as claimed in claim 9, wherein the elevations comprise a plurality of chamfered shielding or a plurality of rib structures.

11. The semiconductor device as claimed in claim 9, wherein a geometric shape of the elevations is directed oppositely to an electric field based on an electric potential difference between the semiconductor chip and the electrically conductive carrier.

12. The semiconductor device as claimed in claim 9, furthermore comprising:
a plurality of electrically conductive layers embedded in the dielectric structure and configured to form at least one capacitor,
wherein a capacitance formed by the at least one capacitor is configured to reduce an electric field strength in a selected spatial region of the semiconductor device.

13. The semiconductor device as claimed in claim 12, wherein a geometric shape and relative arrangement of the plurality of electrically conductive layers are configured to lengthen a discharge path extending from the semiconductor chip through the dielectric structure to the electrically conductive carrier.

14. The semiconductor device as claimed in claim 12, wherein:
at least one electrically conductive layer of the plurality of electrically conductive layers is electrically connected to an electrical output, and
the electrical output outputs a signal if a partial discharge occurs between the semiconductor chip and the at least one electrically conductive layer in the dielectric structure.

15. The semiconductor device as claimed in claim 9, wherein the dielectric structure is arranged directly on the electrically conductive carrier.

16. The semiconductor device as claimed in claim 9, wherein the dielectric structure is produced based on a 3D printing method.

17. The semiconductor device as claimed in claim 9, furthermore comprising:
an electrically conductive coating arranged between the mounting surface of the dielectric structure and the semiconductor chip,
wherein the electrically conductive coating is configured to reduce an electric field strength in a selected spatial region of the semiconductor device.

18. The semiconductor device as claimed in claim 9, furthermore comprising:
at least one bond wire,
wherein the elevations are configured to mechanically support the at least one bond wire in order to prevent a sagging or a bending of the at least one bond wire.

19. A method for producing a semiconductor device, wherein the method comprises:
fabricating a dielectric wafer based on a molding technique, wherein the dielectric wafer has a plurality of depressions;
singulating the dielectric wafer into a plurality of dielectric shells;
mounting a semiconductor chip in a dielectric shell of the plurality of dielectric shells; and
mounting the dielectric shell on an electrically conductive carrier, wherein the dielectric shell galvanically isolates the semiconductor chip and the electrically conductive carrier from one another.

20. The method as claimed in claim 19, furthermore comprising at least one of:
forming a plurality of depressions in a surface of the dielectric shell, wherein the plurality of depressions are dcsigncdconfigured to enlarge a creepage path between the semiconductor chip and the electrically conductive carrier, or
coating a base surface of the dielectric shell with an electrically conductive coating, wherein the semiconductor chip is arranged on the electrically conductive coating.

21. (canceled)
